(19) United States
(12) Patent Application Publication
(10) Pub. No.: US 2022/0406998 A1
(43) Pub. Date: Dec. 22, 2022

(54) ELECTRONIC SYNAPSE DEVICE AND METHOD OF FORMING THE SAME

(71) Applicant: Agency for Science, Technology and Research, Singapore (SG)

(72) Inventors: Wen Dong Song, Singapore (SG); Hock Koon Lee, Singapore (SG); Weijie Wang, Singapore (SG); Yao Zhu, Singapore (SG)

(21) Appl. No.: 17/777,942

(22) PCT Filed: Nov. 22, 2019
(86) PCT No.: PCT/SG2019/050573

§ 371 Date: May 18, 2022

(51) Int. Cl. H01L 45/00; G06N 3/063

(52) U.S. Cl. CPC H01L 45/085; H01L 45/1658; G06N 3/063; H01L 45/144; H01L 45/1206; H01L 45/1253

(57) ABSTRACT

Various embodiments may provide an electronic synapse device. The electronic synapse device may include a body including a doped chalcogenide layer including a chalcogenide material and a dopant. The electronic synapse device may also include a drain electrode in contact with the body. The electronic synapse device may further include a source electrode in contact with the body. The electronic synapse device may additionally include a gate electrode including an electrode contact layer in contact with the doped chalcogenide layer. The electrode contact layer may be any one selected from a group consisting of an electrically conductive layer including an electrically conductive material and a dopant layer including the dopant.

### TECHNICAL FIELD

Various aspects of this disclosure relate to an electronic synapse device. Various aspects of this disclosure relate to a method of forming an electronic synapse device.

### BACKGROUND

A human brain has about 10¹¹ neurons interconnected with approximately 10¹⁵ synapses. The neurons function as signal-processing units, while the synapses act as signal transmission units and also as memory storage to store information. Synaptic weight or plasticity change in biological synapses exhibits gradual changes or changes of an analog nature. This gradual change requires that an electronic synaptic device to have also multiple states.

Conventional two-terminal electronic synaptic devices based on phase change memory (PCM), resistive random-access memory (RRAM) and ferroelectric random-access memory (FeRAM) exhibit non-linear conductance change and unstable analog characteristics.

In order to overcome the non-idealities of two-terminal electronic synaptic devices, three-terminal electronic synapse devices have been studied. Stable analog characteristics and linear changes of the conductance have been demonstrated in three-terminal synapse devices due to the decoupling of write/read operations using a gate electrode to tune the conductance state. However, most three-terminal electronic synapse devices face complementary metal oxide semiconductor (CMOS) compatibility issues.

### SUMMARY

Various embodiments may provide an electronic synapse device. The electronic synapse device may include a body including a doped chalcogenide layer including a chalcogenide material and a dopant. The electronic synapse device may also include a drain electrode in contact with the body. The electronic synapse device may further include a source electrode in contact with the body. The electronic synapse device may additionally include a gate electrode including an electrode contact layer in contact with the doped chalcogenide layer. The electrode contact layer may be any one selected from a group consisting of an electrically conductive layer including an electrically conductive material and a dopant layer including the dopant.

Various embodiments may provide a method of forming an electronic synapse device. The method may include forming a body including a doped chalcogenide layer including a chalcogenide material and a dopant. The method may also include forming a drain electrode in contact with the body. The method may further include forming a source electrode in contact with the body. The method may additionally include forming a gate electrode including an electrode contact layer in contact with the doped chalcogenide layer. The electrode contact layer may be any one selected from a group consisting of an electrically conductive layer including an electrically conductive material and a dopant layer comprising the dopant.

### BRIEF DESCRIPTION OF THE DRAWINGS

The invention will be better understood with reference to the detailed description when considered in conjunction with the non-limiting examples and the accompanying drawings, in which: FIG. 1 is a general illustration of an electronic synapse device according to various embodiments.

FIG. 2A shows a cross-sectional schematic diagram of a three-terminal electronic synapse device according to various embodiments.

FIG. 2B shows a cross-sectional schematic diagram of another three-terminal electronic synapse device according to various embodiments.

FIG. 3A is a general illustration of a method of forming an electronic synapse device according to various embodiments.

FIG. 3B is a general illustration of a method of forming a three-terminal electronic synapse device according to various embodiments.

FIG. 4 illustrates different methods of forming electronic synapse devices according to various embodiments.

FIG. 5A shows a schematic diagram of a three-terminal electronic synapse device according to various embodiments.

FIG. 5B is a plot of current (in micro-amperes or μA) as a function of voltage (in volts or V) illustrating the current-voltage (I-V) characteristics of the three-terminal electronic synapse device shown in FIG. 5A undergoing consecutive direct current (DC) sweeps in SET processes.

FIG. 5C is a plot of current (in micro-amperes or μA) as a function of voltage (in volts or V) illustrating the current-voltage (I-V) characteristics of the three-terminal electronic synapse device shown in FIG. 5A undergoing consecutive direct current (DC) sweeps RESET processes.

FIG. 5D is a plot of conductance GDS (in nano-siemens or nS) as a function of sweeps of the device shown in FIG. 5A according to various embodiments.

FIG. 6A shows a plot of current (in micro-amperes or μA) as a function of voltage (in volts or V) illustrating the current-voltage (I-V) characteristics of the three-terminal electronic synapse device according to various embodiments after annealing 1 minute at 160° C.

FIG. 6B is a plot of conductance GDS (in nano-siemens or nS) as a function of sweeps of the annealed device according to various embodiments.

FIG. 7A shows a plot of normalized impurity concentration (N/N₀)/normalized intensity as a function of the thickness (in nanometers or nm) showing the intensity/impurity distribution of silver (Ag) in germanium-antimony-tellurium (GST) layer using X-ray photoelectron spectroscopy (XPS) depth profile of a multilayer structure which has been annealed at 50° C. for 30 minutes according to various embodiments.

FIG. 7B shows a plot of normalized impurity concentration (N/N₀)/normalized intensity as a function of the thickness (in nanometers or nm) showing the intensity/impurity distribution of silver (Ag) in germanium-antimony-tellurium (GST) layer using X-ray photoelectron spectroscopy (XPS) depth profile of a multilayer structure which has been annealed at 80° C. for 30 minutes according to various embodiments.

FIG. 8A shows a plot of normalized impurity concentration (N/N₀)/normalized intensity as a function of the thickness (in nanometers or nm) showing the intensity/impurity distribution of copper (Cu) in germanium-antimony-tellurium (GST) layer using X-ray photoelectron spectroscopy (XPS) depth profile of a multilayer structure which has been annealed at 50° C. for 30 minutes according to various embodiments.

FIG. 8B shows a plot of normalized impurity concentration (N/N₀)/normalized intensity as a function of the thickness (in nanometers or nm) showing the intensity/impurity distribution of copper (Cu) in germanium-antimony-tellurium (GST) layer using X-ray photoelectron spectroscopy (XPS) depth profile of a multilayer structure which has been annealed at 80° C. for 30 minutes according to various embodiments.

FIG. 9A shows a plot of normalized impurity concentration (N/N₀)/normalized intensity as a function of the thickness (in nanometers or nm) showing the intensity/impurity distribution of iridium (Ir) in germanium-antimony-tellurium (GST) layer using X-ray photoelectron spectroscopy (XPS) depth profile of a multilayer structure which has been annealed at 50° C. for 30 minutes according to various embodiments.

FIG. 9B shows a plot of normalized impurity concentration (N/N₀)/normalized intensity as a function of the thickness (in nanometers or nm) showing the intensity/impurity distribution of iridium (Ir) in germanium-antimony-tellurium (GST) layer using X-ray photoelectron spectroscopy (XPS) depth profile of a multilayer structure which has been annealed at 80° C. for 30 minutes according to various embodiments.

FIG. 10A is a high-resolution transmission electron microscopy (HRTEM) image of a sample according to various embodiments with the inset showing fast Fourier transformed (FFT) patterns.

FIG. 10B is another high-resolution transmission electron microscopy (HRTEM) image of the sample according to various embodiments.

FIG. 10C is a plot of intensity as a function of thickness (in nanometers or nm) showing the X-ray photoelectron spectroscopy (XPS) depth profile of the sample according to various embodiments.

FIG. 11A is a schematic of germanium-antimony-tellurium Ge₂Sb₂Te₅ (GST).

FIG. 11B illustrates the shifting of doped ions in a germanium-antimony-tellurium (GST) layer of the device according to various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, and logical changes may be made without departing from the scope of the invention. The various embodiments are not necessarily mutually exclusive, as some embodiments can be combined with one or more other embodiments to form new embodiments.

Embodiments described in the context of one of the methods or electronic synapse devices is analogously valid for the other methods or electronic synapse devices. Similarly, embodiments described in the context of a method are analogously valid for an electronic synapse device, and vice versa.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may also be used herein to mean that the deposited material may be formed “indirectly on” the implied side or surface with one or more additional layers being arranged between the implied side or surface and the deposited material. In other words, a first layer “over” a second layer may refer to the first layer directly on the second layer, or that the first layer and the second layer are separated by one or more intervening layers.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance.

As used herein, the term “and/or” includes any and all combinations of one or more of the associated listed items.

Various embodiments may seek to address or mitigate the abovementioned issues.

Various embodiments may be compatible with CMOS processing.

FIG. 1 is a general illustration of an electronic synapse device 100 according to various embodiments. The electronic synapse device 100 may include a body 102 including a doped chalcogenide layer including a chalcogenide material and a dopant. The electronic synapse device 100 may also include a drain electrode 104 in contact with the body 102. The electronic synapse device 100 may further include a source electrode 106 in contact with the body 102. The electronic synapse device 100 may additionally include a gate electrode 108 including an electrode contact layer in contact with the doped chalcogenide layer. The electrode contact layer may be any one selected from a group consisting of an electrically conductive layer including an electrically conductive material and a dopant layer including the dopant.

In other words, the electronic synapse device 100 may also include a body 102 including a chalcogenide layer doped with a dopant. The electronic synapse device 100 may also include a drain electrode 104 and a source electrode 106 in contact with the body 102. An electrode contact layer of the gate electrode 108 may be in contact with the doped chalcogenide layer. The electrode contact layer may be either a dopant layer including the dopant, or an electrically conductive layer including an electrically conductive material.

For avoidance of doubt, FIG. 1 is an illustration of the features of a device 100 according to various embodiments, and does not serve to indicate or limit the sizes, shapes, arrangements etc. of the various features.

In various embodiments, the body 102 may include a substrate. The chalcogenide layer may be on the substrate.

In various embodiments, the electrode contact layer may be the dopant layer including the dopant. The electrically conductive layer may be on the electrode contact layer. In other words, the electrically conductive layer may be spaced apart from the doped chalcogenide layer, and may not be in contact with the doped chalcogenide layer. The doped chalcogenide layer may be formed by diffusion of the dopant (from the dopant layer) into an undoped chalcogenide layer.

In various other embodiments, the electrode contact layer may be the dopant layer including the dopant. The electrically conductive layer may be on the electrode contact layer, i.e. the electrically conductive layer may be spaced apart from the doped chalcogenide layer. At least a portion of the dopant in the doped chalcogenide layer may be introduced by a deposition process.

In yet various other embodiments, the electrode contact layer may be the electrically conductive layer including an electrically conductive material. The electrically conductive material may not diffuse or react with the chalcogenide material easily. The dopant in the doped chalcogenide layer may be introduced by a deposition process.

In various embodiments, the electrically conductive material may include a metal element, a metal alloy, or any other suitable electrically conductive material. In various embodiments, the electrically conductive material selected may be any one selected from a group consisting of aluminum (Al), copper (Cu), silver (Ag), titanium-tungsten (TiW), and titanium nitride (TiN).

In various embodiments, the dopant may be an element that easily diffuses into a chalcogenide material. In various embodiments, the dopant may be any one selected from a group consisting of carbon (C), magnesium (Mg), aluminum (Al), silicon (Si), scandium (Sc), titanium (Ti), vanadium (V), chromium (Cr), manganese (Mn), iron (Fe), cobalt (Co), nickel (Ni), copper (Cu), zinc (Zn), germanium (Ge), zirconium (Zr), molybdenum (Mo), silver (Ag), indium (In), and tin (Sn).

In various embodiments, the chalcogenide material may be germanium-antimony-tellurium (Ge—Sb—Te), or an element-doped Ge—Sb—Te based material. In various embodiments, the chalcogenide material may be any one selected from a group consisting of GeTe, Ge₂Sb₂Te₅, GeSb₂Te₄, GeSb₄Te₇, and Sb₂Te₃. In various embodiments, the chalcogenide material may be in an amorphous phase. In various other embodiments, the chalcogenide material may be in a crystalline phase or polycrystalline phase.

In various embodiments, the source electrode and the drain electrode may include a metal, an alloy or any other suitable conductive material. In various embodiments, the source electrode 106 and the drain electrode 104 may include any one material selected from a group consisting of aluminum (Al), copper (Cu), silver (Ag), titanium-tungsten (TiW), and titanium nitride (TiN).

In various embodiments, the electronic synapse device 100 may be a non-volatile memory.

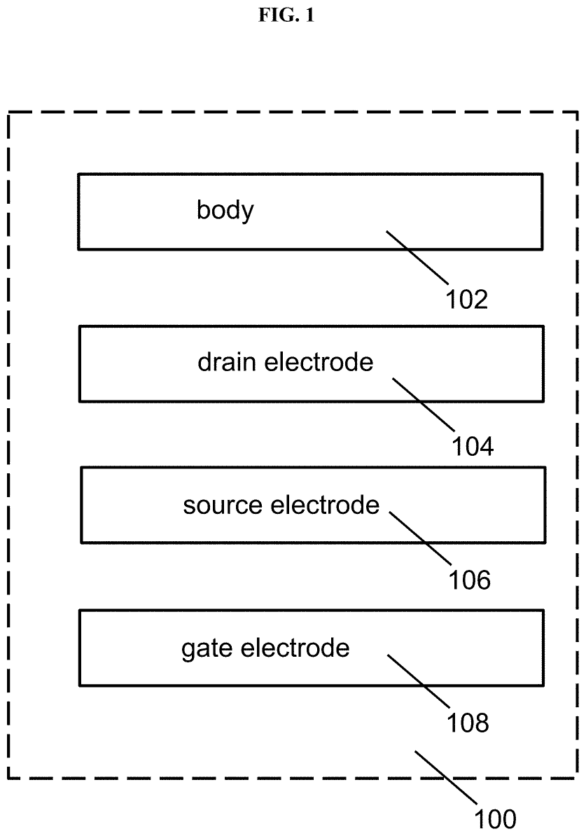

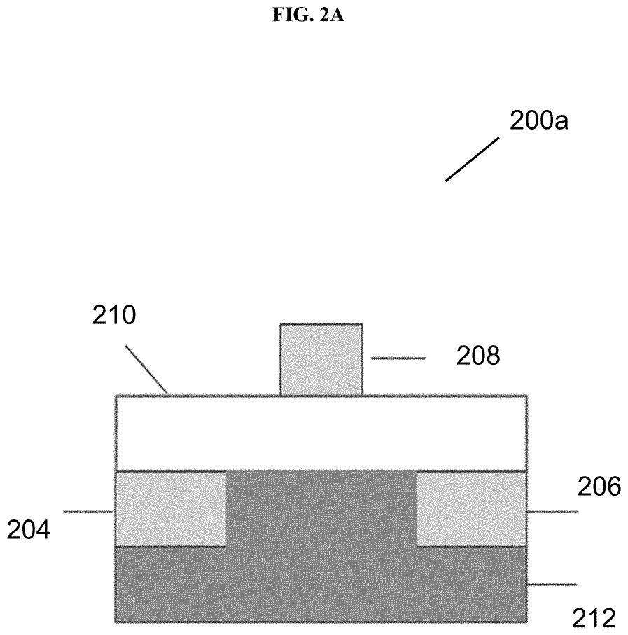

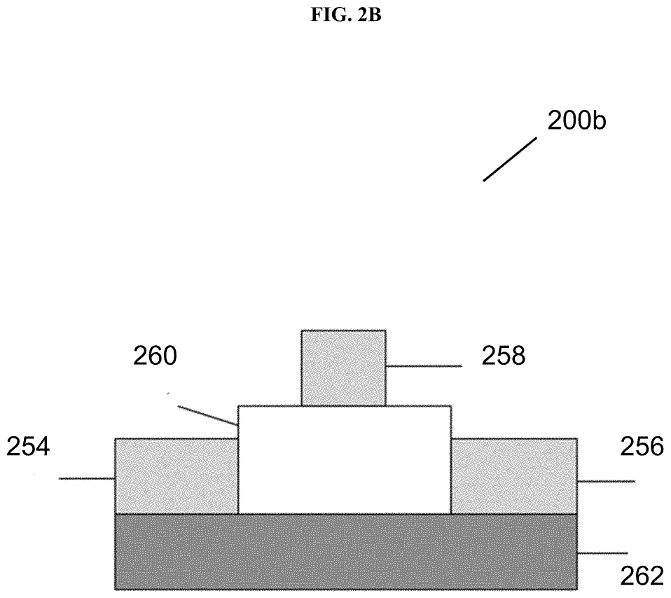

FIG. 2A shows a cross-sectional schematic diagram of a three-terminal electronic synapse device 200a according to various embodiments. The three-terminal electronic synapse device 200a may include a body including a doped chalcogenide layer 210 including a chalcogenide material and a dopant. The body may also include a substrate 212. The doped chalcogenide layer 210 may be in contact with the substrate 212. The three-terminal electronic synapse device 200a may also include a drain electrode 204 in contact with the body, i.e. the doped chalcogenide layer 210. The three-terminal electronic synapse device 200a may further include a source electrode 206 in contact with the body, i.e. the doped chalcogenide layer 210. The three-terminal electronic synapse device 200a may additionally include a gate electrode 208 in contact with the body, i.e. the doped chalcogenide layer 210. As shown in FIG. 2A, the substrate 212 may include recesses to accommodate the drain electrode 204 and the source electrode 206. The doped chalcogenide layer 210 may extend over an entire surface of the device's substrate 212.

FIG. 2B shows a cross-sectional schematic diagram of another three-terminal electronic synapse device 200b according to various embodiments. The three-terminal electronic synapse device 200b may include a body including a substrate 262, and a doped chalcogenide layer 260 on the substrate 262. The three-terminal electronic synapse device 200b may include a drain electrode 254 and a source electrode 256 in contact with the doped chalcogenide layer 260. The three-terminal electronic synapse device 200b may additionally include a gate electrode 258 in contact with the body, i.e. the doped chalcogenide layer 260. The doped chalcogenide layer 260 may occupy a portion of the device's planar substrate 262. The drain electrode 254 and the source electrode 256 may occupy remaining portions of the substrate 262

When a positive (or negative) voltage or an electrical field is applied across the gate electrode 208/258 and the source electrode 206/256, the dopants, i.e. doped-ions, in the element-doped chalcogenide layer 210/260 may shift from one vacancy to another in the element-doped chalcogenide material under the influence of the electric field generated by the voltage. The ion shift in the element-doped chalcogenide layer 210/260 may lead to changes of electrical conduction activation energy through the variation of band gap and depth of the trap states, which result in the variation of conductance in the element-doped chalcogenide layer 210/260. The resistance between the source electrode 206, 256 and the drain electrode 204, 254 may gradually change as an electric field is applied between the gate electrode 208/258 and the source electrode 206/256.

Various embodiments may provide a three-terminal electronic synapse device with stable analog characteristics. Various embodiments may provide a three-terminal electronic synapse device with the changes of the conductance.

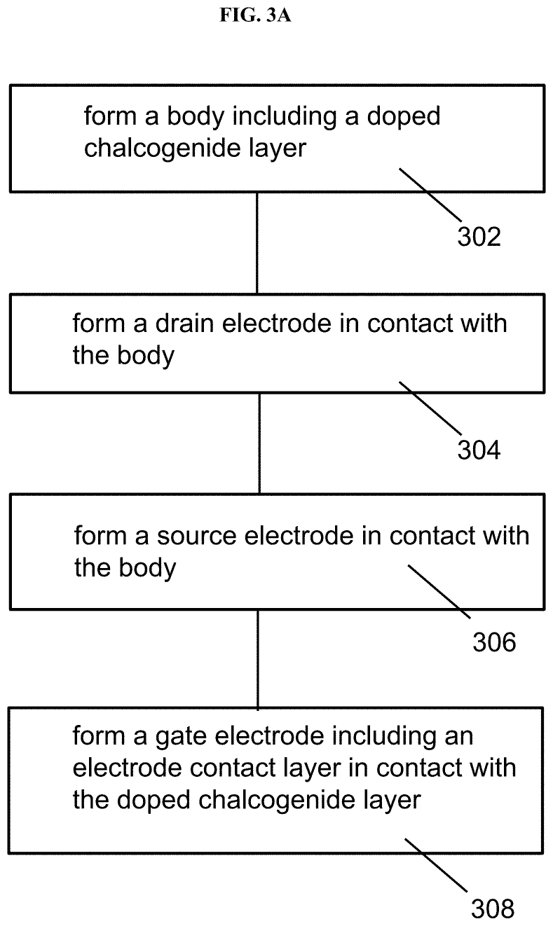

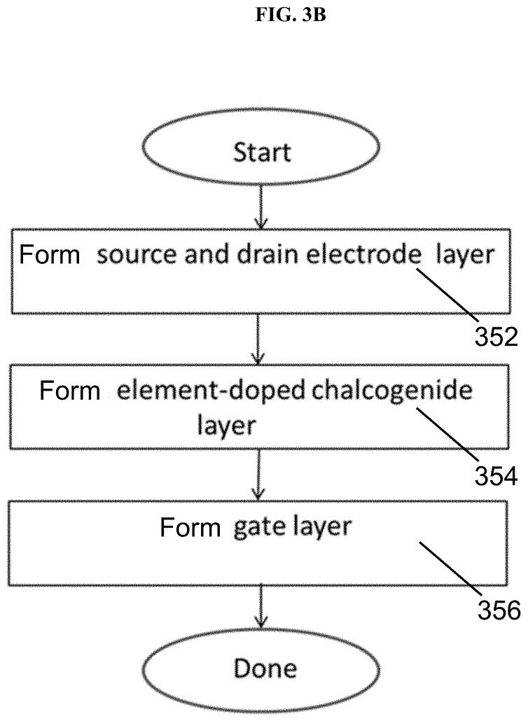

FIG. 3A is a general illustration of a method of forming an electronic synapse device according to various embodiments. The method may include, in 302, forming a body including a doped chalcogenide layer including a chalcogenide material and a dopant. The method may also include, in 304, forming a drain electrode in contact with the body. The method may further include, in 306, forming a source electrode in contact with the body. The method may additionally include, in 308, forming a gate electrode including an electrode contact layer in contact with the doped chalcogenide layer. The electrode contact layer may be any one selected from a group consisting of an electrically conductive layer including an electrically conductive material and a dopant layer comprising the dopant.

In other words, the method may include forming the body including the doped chalcogenide layer, the source electrode, the drain electrode, and a gate electrode including an electrode contact layer which is in contact with the doped chalcogenide layer. The electrode contact layer may either be an electrically conductive layer or a dopant layer.

For avoidance of doubt, FIG. 3A is not intended to be in sequence. For instance, in various embodiments, step 304 may occur before step 306, at the same time as step 306, or after step 306.

In various embodiments, the electrode contact layer may be the dopant layer including the dopant. The electrically conductive layer may be on the electrode contact layer. The doped chalcogenide layer may be formed by diffusion of the dopant into an undoped chalcogenide layer. The method may first include forming or providing an undoped chalcogenide layer, followed by forming a dopant layer on or in contact with the undoped chalcogenide layer. Dopants may then diffuse from the dopant layer into the undoped chalcogenide layer to form the doped chalcogenide layer.

In various other embodiments, the electrode contact layer may be a dopant layer including the dopant. The electrically conductive layer may be on the electrode contact layer. At least a portion of the dopant in the doped chalcogenide layer may be introduced by a deposition process. In other words, the method may include first forming an initial doped chalcogenide layer including the chalcogenide material and the dopant using one or more deposition processes. The method may further include forming the dopant layer on or in contact with the initial doped chalcogenide layer. Dopants in the dopant layer may then diffuse into the initial doped chalcogenide layer, thereby increasing a level of dopants in the initial doped chalcogenide layer to form the doped chalcogenide layer.

In yet various other embodiments, the electrode contact layer may be the electrically conductive layer including an electrically conductive material. The dopant in the doped chalcogenide layer may be introduced by a deposition process. The method may include forming the doped chalcogenide material and the dopant using one or more deposition processes. The electronic synapse device may not include a dopant layer.

In various embodiments, the electronic synapse device may include a substrate. The method may include forming the body, the drain electrode, the source electrode and/or the gate electrode on or over the substrate.

In various embodiments, the electrically conductive material may include a metal element, a metal alloy, or any other suitable electrically conductive material. In various embodiments, the electrically conductive material may be any one selected from a group consisting of aluminum (Al), copper (Cu), silver (Ag), titanium-tungsten (TiW), and titanium nitride (TiN).

In various embodiments, the body including the doped chalcogenide layer is formed before forming the source electrode and the drain electrode.

In various embodiments, the drain electrode, the source electrode, the gate electrode and/or the body are formed by any one deposition process selected from a group consisting of atomic layer deposition (ALD), chemical vapor deposition (CVD), pulsed laser deposition (PLD), molecular-beam epitaxy (MBE) and physical vapor deposition (PVD).

In various embodiments, the method may also include forming one or more further chalcogenide layers and forming one or more further dopant layers.

In various embodiments, the chalcogenide layer and the one or more chalcogenide layers may form an alternating arrangement with the dopant layer and the one or more further dopant layers. In other words, an arrangement including alternate layers of chalcogenide material and the dopant may be formed (e.g. arrangement of dopant/chalcogenide/dopant/chalcogenide).

In various embodiments, the dopant may be an element that easily diffuses into a chalcogenide material. In various embodiments, the dopant may be any one selected from a group consisting of carbon (C), magnesium (Mg), aluminum (Al), silicon (Si), scandium (Sc), titanium (Ti), vanadium (V), chromium (Cr), manganese (Mn), iron (Fe), cobalt (Co), nickel (Ni), copper (Cu), zinc (Zn), germanium (Ge), zirconium (Zr), molybdenum (Mo), silver (Ag), indium (In), and tin (Sn).

In various embodiments, the chalcogenide material may be germanium-antimony-tellurium (Ge—Sb—Te), or an element-doped Ge—Sb—Te based material. In various embodiments, the chalcogenide material may be any one selected from a group consisting of GeTe, Ge₂Sb₂Te₅, GeSb₂Te₄, GeSb₄Te₇, and Sb₂Te₃.

In various embodiments, the source electrode and the drain electrode may include a metal, an alloy or any other suitable conductive material. In various embodiments, the source electrode and the drain electrode may include any one material selected from a group consisting of aluminum (Al), copper (Cu), silver (Ag), titanium-tungsten (TiW), and titanium nitride (TiN).

FIG. 3B is a general illustration of a method of forming a three-terminal electronic synapse device according to various embodiments. The method may include, in 352, forming a source electrode including a source electrode material and a drain electrode including a drain electrode material. The method may also include, in 354, forming an element-doped chalcogenide layer in contact with the source electrode and the drain electrode. The method may also include, in 356, forming a gate electrode including a gate electrode material in contact with the element-doped chalcogenide layer.

In other words, forming the three-terminal electronic synapse device may include fabricating source and drain electrodes, fabricating an element-doped chalcogenide layer, and fabricating the gate electrode.

For avoidance of doubt, FIG. 3B is not intended to be in sequence.

In various embodiments, the source electrode, the drain electrode, the element-doped chalcogenide layer, and/or the gate electrode may be formed by any one deposition process selected from a group consisting of atomic layer deposition (ALD), chemical vapor deposition (CVD), pulsed laser deposition (PLD), molecular-beam epitaxy (MBE) and physical vapor deposition (PVD).

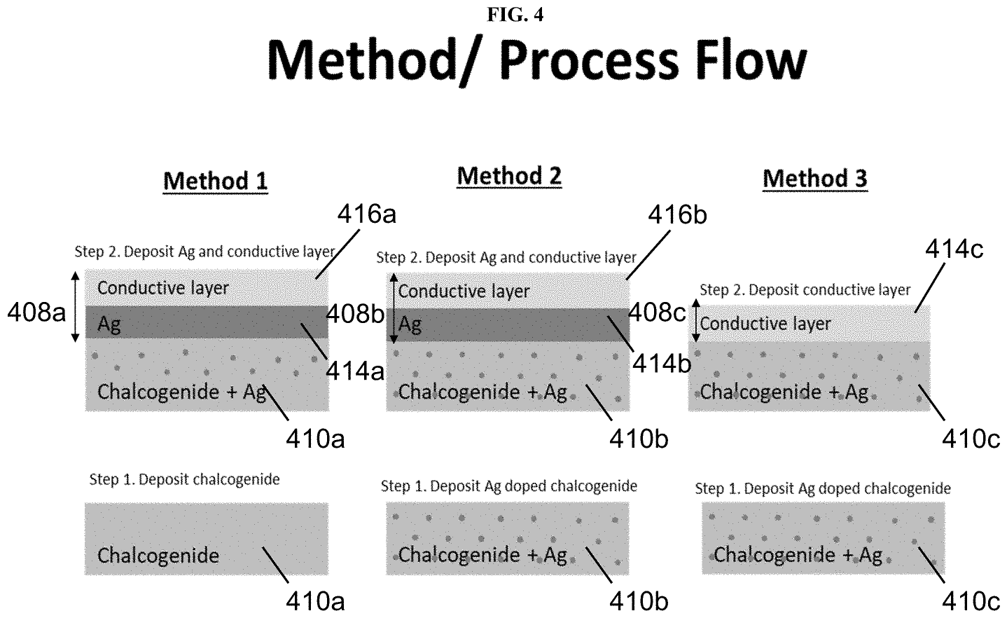

FIG. 4 illustrates different methods of forming electronic synapse devices according to various embodiments.

For method 1, the resultant device may include an electrode contact layer 414a in contact with the doped chalcogenide layer 410a (e.g. Ag doped chalcogenide), the electrode contact layer 414a being a dopant layer including the dopant (e.g. Ag). The electrically conductive layer 416a may be on the electrode contact layer 414a. Step 1 shows that the chalcogenide layer 410a may be initially undoped. Step 2 shows forming a dopant layer 414a on or in contact with the undoped chalcogenide layer 410a. Dopants may then diffuse from the dopant layer 414a into the undoped chalcogenide layer 410a to form the doped chalcogenide layer 410a. The method may also include forming the electrically conductive layer 416a on the electrode contact layer 414a. The gate electrode 408a may include the electrically conductive layer 416a and the electrode contact layer 414a.

For method 2, the resultant device may include an electrode contact layer 414b in contact with the doped chalcogenide layer 410b (e.g. Ag doped chalcogenide), the electrode contact layer 414b being a dopant layer including the dopant. The electrically conductive layer 416b may be on the electrode contact layer 414b. At least a portion of the dopant in the doped chalcogenide layer 410b may be introduced into an undoped chalcogenide layer by a deposition process. In other words, as shown in Step 1, the method may include first forming an initial doped chalcogenide layer 410b including the chalcogenide material and the dopant using one or more deposition processes. The method may further include, as shown in Step 2, forming the dopant layer 414b on or in contact with the initial doped chalcogenide layer 410b. Dopants in the dopant layer 414b may then diffuse into the initial doped chalcogenide layer 410b, thereby increasing a level of dopants in the initial doped chalcogenide layer to form the doped chalcogenide layer 410b. The method may also include forming the electrically conductive layer 416b on the electrode contact layer 414b. The gate electrode 408b may include the electrically conductive layer and the electrode contact layer 414b. The dopant layer 414b may provide additional dopants to the already doped chalcogenide layer 410b.

For method 3, the resultant device may include an electrode contact layer 414c in contact with the doped chalcogenide layer 410c (e.g. Ag doped chalcogenide), the electrode contact layer 414c being an electrically conductive layer including an electrically conductive material. The dopant in the doped chalcogenide layer 410c may be introduced by a deposition process. The method may include depositing the doped chalcogenide material and the dopant using one or more deposition processes to form the doped chalcogenide layer 410c as shown in Step 1. The method may further include forming the electrode contact layer 414c on the doped chalcogenide layer 410c as shown in Step 2. The electronic synapse device may not include a dopant layer. The gate electrode 408c may consist of only the electrode contact layer 414c, i.e. the electrically conductive layer including an electrically conductive material. The electrically conductive material may be a metal element, a metal alloy, or any other suitable conductive material which does not diffuse or react with the chalcogenide material easily.

Based on experimental data, various embodiments may provide symmetrical and linear potentiation and depression. Various embodiments may be configured for non-volatile read and non-volatile write.

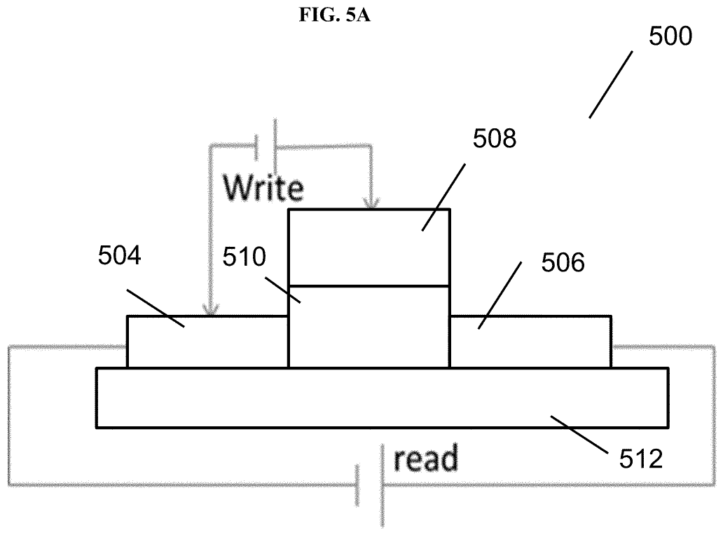

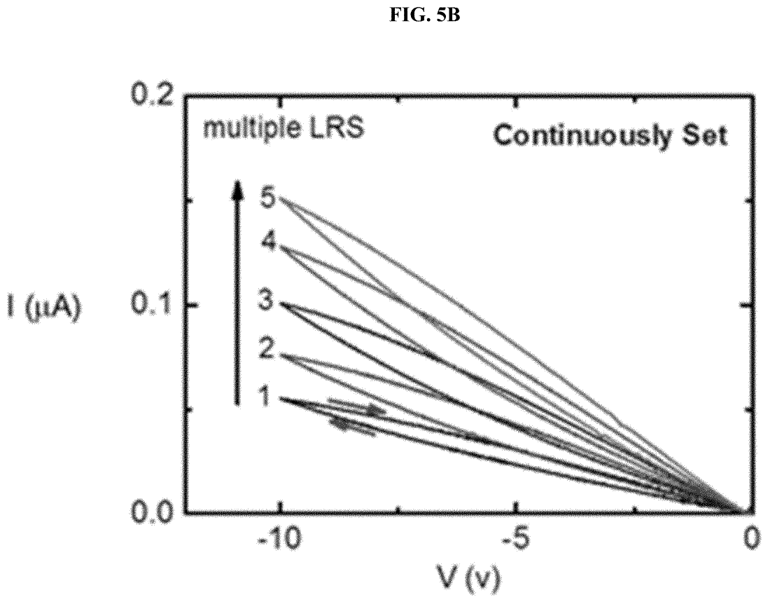

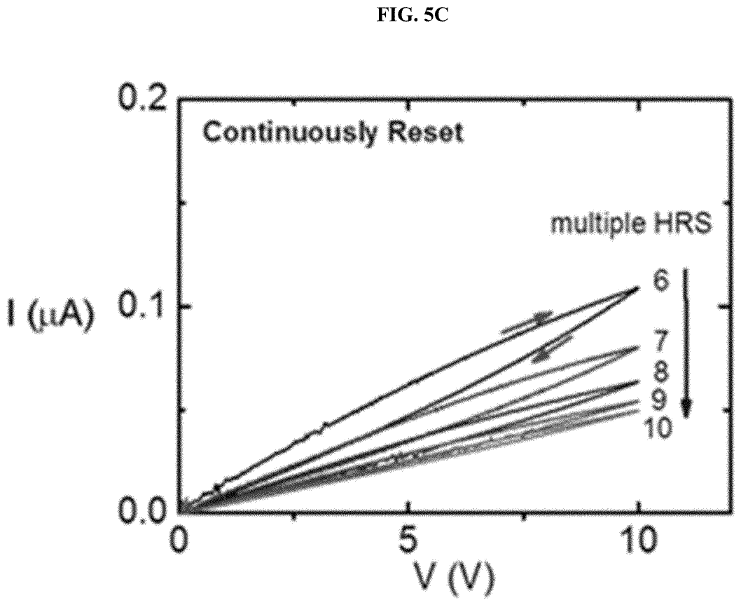

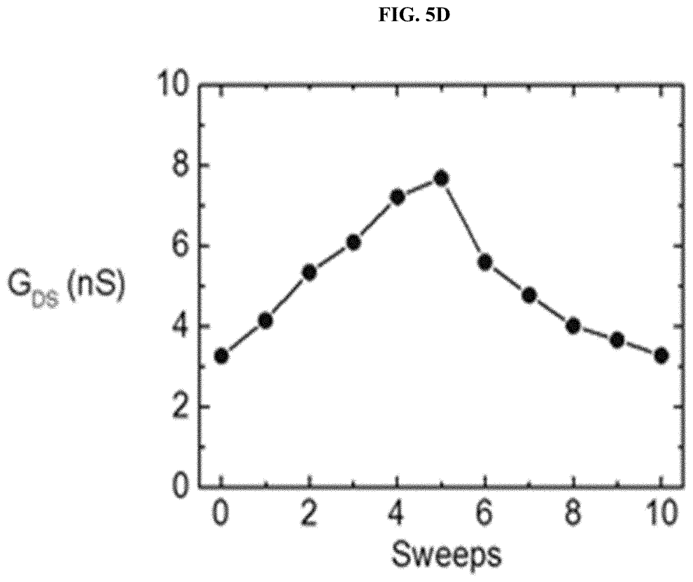

FIG. 5A shows a schematic diagram of a three-terminal electronic synapse device 500 according to various embodiments. The three-terminal electronic synapse device 500 may include a drain electrode 504 including a drain electrode material (TiW) and a source electrode 506 including a source electrode material (TiW). The three-terminal electronic synapse device 500 may also include an element-doped chalcogenide layer 510 (including Ag-doped Ge₂Sb₂Te₅) in contact with the source electrode 506 and the drain electrode 504. The three-terminal electronic synapse device may further include a gate electrode 508 (Ag). An external voltage (or current) may be applied between the gate electrode 508 and the source electrode 504 for write operation. A small voltage (or current) may be applied between the source electrode 506 and the drain electrode 504 for read operation.

FIG. 5B is a plot of current (in micro-amperes or μA) as a function of voltage (in volts or V) illustrating the current-voltage (I-V) characteristics of the three-terminal electronic synapse device 500 shown in FIG. 5A undergoing consecutive direct current (DC) sweeps in SET processes. FIG. 5C is a plot of current (in micro-amperes or μA) as a function of voltage (in volts or V) illustrating the current-voltage (I-V) characteristics of the three-terminal electronic synapse device 500 shown in FIG. 5A undergoing consecutive direct current (DC) sweeps RESET processes.

A negative voltage on the gate electrode may be applied to induce the SET process which switches the device from high resistance state (HRS) to low resistance state (LRS). A positive voltage on the gate electrode may be applied to induce the RESET process which switches the device from LRS to HRS. As shown in FIGS. 5A-B, the current increases gradually with consecutive negative voltage sweeps and decreases gradually with consecutive positive voltage sweeps.

The conductance between the source electrode 506 and the drain electrode 504 may be measured for each sweep during SET and RESET processes. FIG. 5D is a plot of conductance GDS (in nano-siemens or nS) as a function of sweeps of the device shown in FIG. 5A according to various embodiments. By decoupling the write/read operations and tuning of the conductance using the gate electrode, the stable analog characteristics and linear changes of the conductance may be observed in this three-terminal synapse device. As shown in FIG. 5D, the conductance continuously increases from 3 nS to 8 nS and decreases from 8 nS to 3 nS during the negative and positive voltage sweeps respectively. The results show that the device according to various embodiments may exhibit analog switching behaviors with multiple states and linear conductance change.

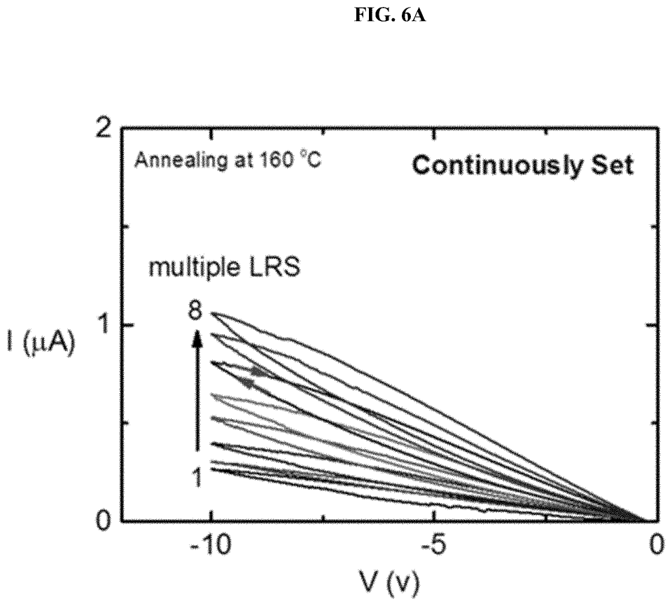

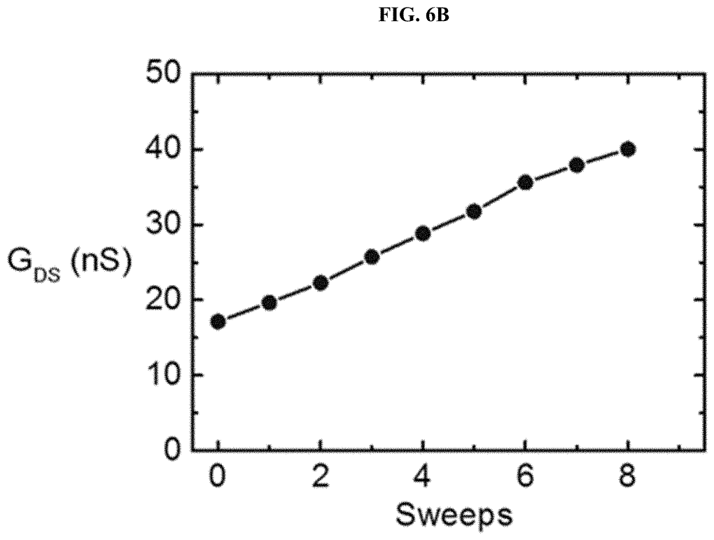

FIG. 6A shows a plot of current (in micro-amperes or μA) as a function of voltage (in volts or V) illustrating the current-voltage (I-V) characteristics of the three-terminal electronic synapse device according to various embodiments after annealing 1 minute at 160° C. After annealing, the element-doped chalcogenide layer (containing Ag-doped Ge₂Sb₂Te₅) in the three-terminal electronic synapse device may change from amorphous to polycrystalline phase. The current may become larger than that shown in FIG. 5B which relates to when the element-doped chalcogenide layer Ag-doped Ge₂Sb₂Te₅ is in amorphous phase. As shown in FIG. 6A, the current may increase gradually with consecutive negative voltage sweeps. FIG. 6B is a plot of conductance GDS (in nano-siemens or nS) as a function of sweeps of the annealed device according to various embodiments. The conductance may continuously increase from 17 nS to 40 nS during the negative voltage sweeps. These demonstrate the device may still exhibit multiple states and analog switching behaviors when the element-doped chalcogenide layer is in the crystalline phase.

For impurity diffusion from a constant source into a semi-infinite solid, the impurity concentration in the solid may be satisfied by the equation N=N₀ {1−erf [x/2(Dt)^{1/2}]}, where erf [x/2(Dt)^{1/2}] represents the error function, N₀ represents a impurity concentration on the solid surface, N represents the impurity concentration at the distance x in the solid, D is the diffusion coefficient and t is the diffusion time. The diffusion length may be provided by L=2(Dt)^{1/2}. The diffusion length may provide a measurement of how far the impurity has propagated in the x-direction by diffusion in time t. Experimentally, the diffusion coefficient D may be related to absolute temperature T by the Arrhenius equation D=D₀ exp(−Eₐ/kBT), where Eₐ is activation energy, kB is the Boltzmann constant and Do is the pre-exponential factor.

When a single dopant layer including a dopant element is deposited onto a chalcogenide layer, the dopant element may diffuse into chalcogenide layer. Since film thickness is in nanoscale and smaller than film area scale, the element diffusion in chalcogenide layer may be considered as one-dimensional diffusion. As long as the chalcogenide layer is thick enough to prevent the element from completely passing through it, it may be assumed that the chalcogenide layer is a semi-infinite solid. Using XPS, the depth profile can be used to measure element concentration distribution in chalcogenide layer. By fitting the experimental data to N/N₀=1−erf (x/L), we can obtain diffusion length and diffusion coefficient of element in chalcogenide layer.

Three samples are (1) stack of 10 nm Ag/100 nm Ge₂Sb₂Te₅/10 nm TiW/Si wafer, (2) stack of 10 nm Cu/100 nm Ge₂Sb₂Te₅/10 nm TiW/Si wafer, and (3) stack of 10 nm Ir/100 nm Ge₂Sb₂Te₅/10 nm TiW/Si wafer. The stacks were formed via deposition in a sputtering system at a pressure of 3 mTorr with an Argon (Ar) flow rate of 48 sccm. The powers used for sputtering TiW, Cu, Ge₂Sb₂Te₅ (GST), Ag and Ir are 150 W, 100 W, 50 W, 50 W and 50 W, respectively. All layers were deposited in vacuum at room temperature. The diffusion annealing of samples was done in a vacuum chamber at different temperatures of 50° C. and 80° C. for 30 mins each. The annealing temperature was selected below the crystalline temperature 140° C. of GST to avoid phase-change effect during diffusion process.

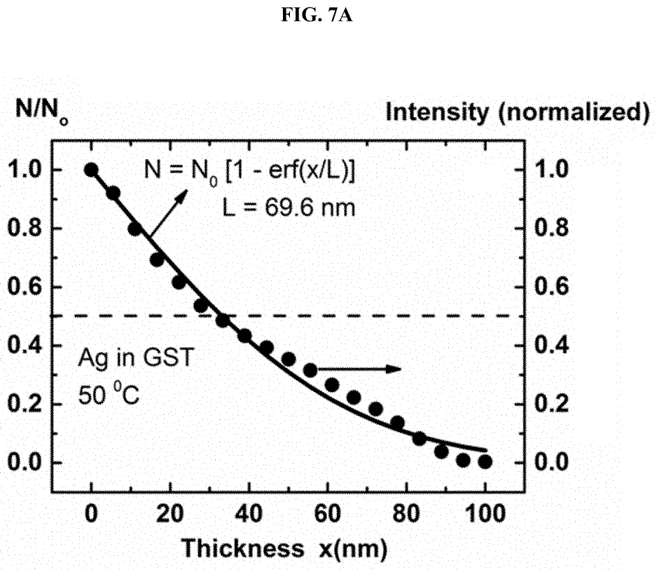

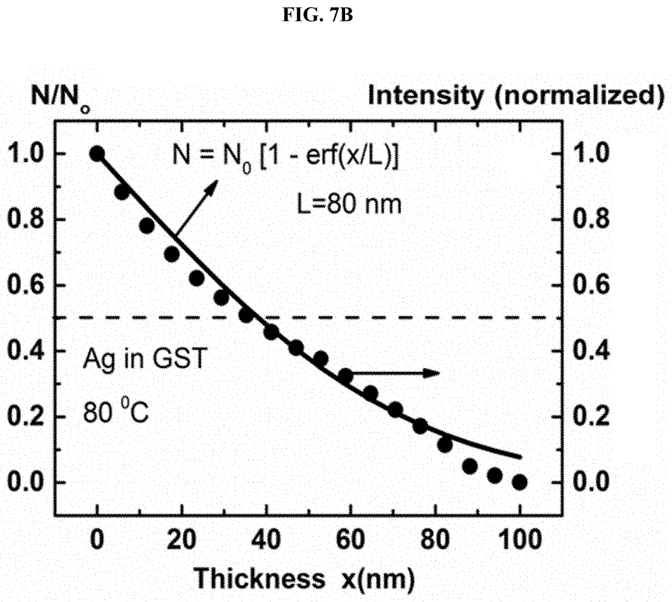

FIG. 7A shows a plot of normalized impurity concentration (N/N₀)/normalized intensity as a function of the thickness (in nanometers or nm) showing the intensity/impurity distribution of silver (Ag) in germanium-antimony-tellurium (GST) layer using X-ray photoelectron spectroscopy (XPS) depth profile of a multilayer structure which has been annealed at 50° C. for 30 minutes according to various embodiments. FIG. 7B shows a plot of normalized impurity concentration (N/N₀)/normalized intensity as a function of the thickness (in nanometers or nm) showing the intensity/impurity distribution of silver (Ag) in germanium-antimony-tellurium (GST) layer using X-ray photoelectron spectroscopy (XPS) depth profile of a multilayer structure which has been annealed at 80° C. for 30 minutes according to various embodiments.

As shown in FIG. 7A, the Ag intensity decreases with thickness of GST layer, which indicates that Ag diffuses into GST layer and that the Ag concentration has an exponentially tapered distribution in GST. By fitting the experimental data to equation N/No=1- erf (x/L), a diffusion length L=69.6 nm is obtained for the sample annealed at 50° C. for 30 mins. The same fitting was performed for the samples annealed at 80° C. for 30 mins. The value of diffusion length is 80 nm as shown in FIG. 7B. According to the relationship between diffusion length and diffusion coefficient L=2(Dt)^{1/2}, the diffusion coefficient is 6.7×10⁻¹⁵ and 8.9×10⁻¹⁵ cm²/s for Ag in GST at 50° C. and 80° C., respectively.

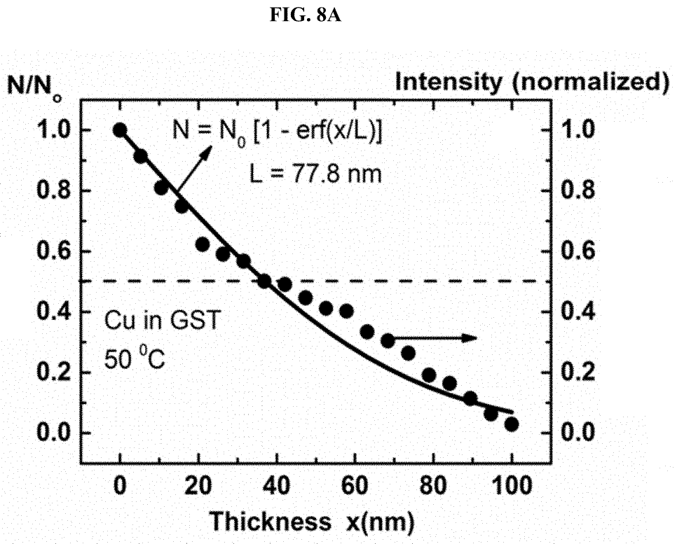

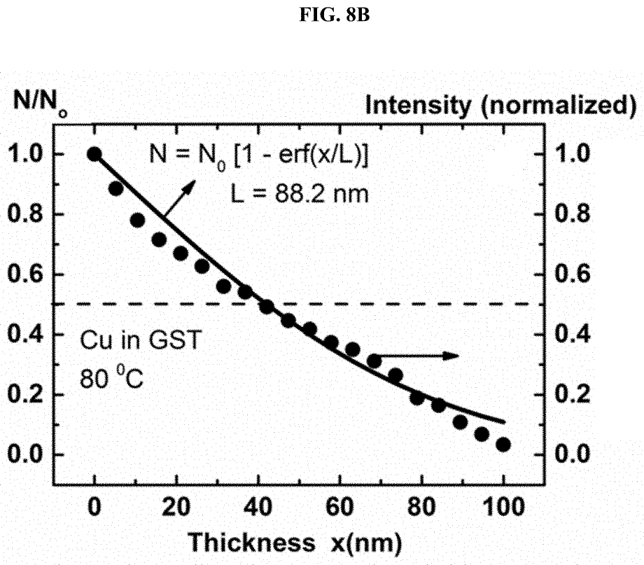

FIG. 8A shows a plot of normalized impurity concentration (N/N₀)/normalized intensity as a function of the thickness (in nanometers or nm) showing the intensity/impurity distribution of copper (Cu) in germanium-antimony-tellurium (GST) layer using X-ray photoelectron spectroscopy (XPS) depth profile of a multilayer structure which has been annealed at 50° C. for 30 minutes according to various embodiments. FIG. 8B shows a plot of normalized impurity concentration (N/N₀)/normalized intensity as a function of the thickness (in nanometers or nm) showing the intensity/impurity distribution of copper (Cu) in germanium-antimony-tellurium (GST) layer using X-ray photoelectron spectroscopy (XPS) depth profile of a multilayer structure which has been annealed at 80° C. for 30 minutes according to various embodiments.

Similar analysis with Ag diffusion in GST is carried. The diffusion length and diffusion coefficient are found to be 77.8 nm, 8.4×10⁻¹⁵ cm²/s respectively for Cu diffusion in GST at 50° C., and 88.2 nm, 1.1x10-¹⁴ cm²/s respectively for Cu diffusion in GST at 80° C. From FIGS. 7A-B and FIG. 8A-B, it may be observed that both diffusion lengths of Ag and Cu in GST are all around 80 nm. If the thickness of GST layer in the devices is less than 80 nm, Cu or Ag may diffuse into whole GST layer. Comparing with Ag diffusion in GST, it was found that Cu is easier diffused into GST due to smaller atomic radius of Cu than that of Ag.

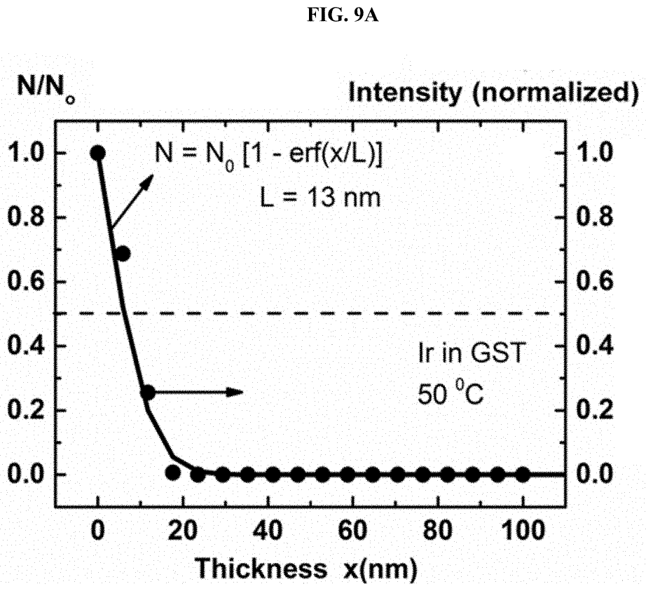

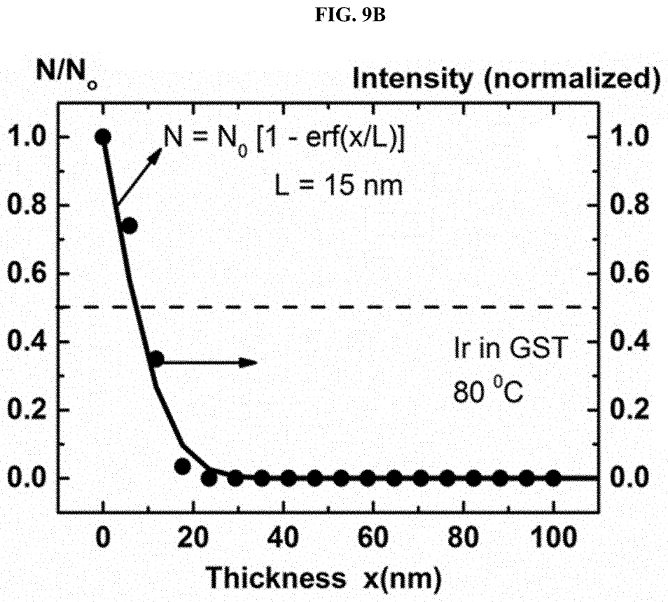

An element with large atomic radius such as iridium (Ir) may be selected to show the effect of large atomic radius on diffusion length and diffusion coefficient. FIG. 9A shows a plot of normalized impurity concentration (N/N₀)/normalized intensity as a function of the thickness (in nanometers or nm) showing the intensity/impurity distribution of iridium (Ir) in germanium-antimony-tellurium (GST) layer using X-ray photoelectron spectroscopy (XPS) depth profile of a multilayer structure which has been annealed at 50° C. for 30 minutes according to various embodiments. FIG. 9B shows a plot of normalized impurity concentration (N/N₀)/normalized intensity as a function of the thickness (in nanometers or nm) showing the intensity/impurity distribution of iridium (Ir) in germanium-antimony-tellurium (GST) layer using X-ray photoelectron spectroscopy (XPS) depth profile of a multilayer structure which has been annealed at 80° C. for 30 minutes according to various embodiments.

One can calculate the diffusion length and diffusion coefficients of Ir in GST with the aid of the theoretical curve fitting to the experimental data. They are respectively 13 nm, 2.3×10⁻¹⁶cm²/s for Ir diffusion in GST at 50° C. and respectively 15 nm, 3.1×10⁻¹⁶ cm²/s for Ir diffusion in GST at 80° C. The diffusion length and the diffusion coefficient are much reduced than those of Cu diffusion in GST and Ag diffusion in GST.

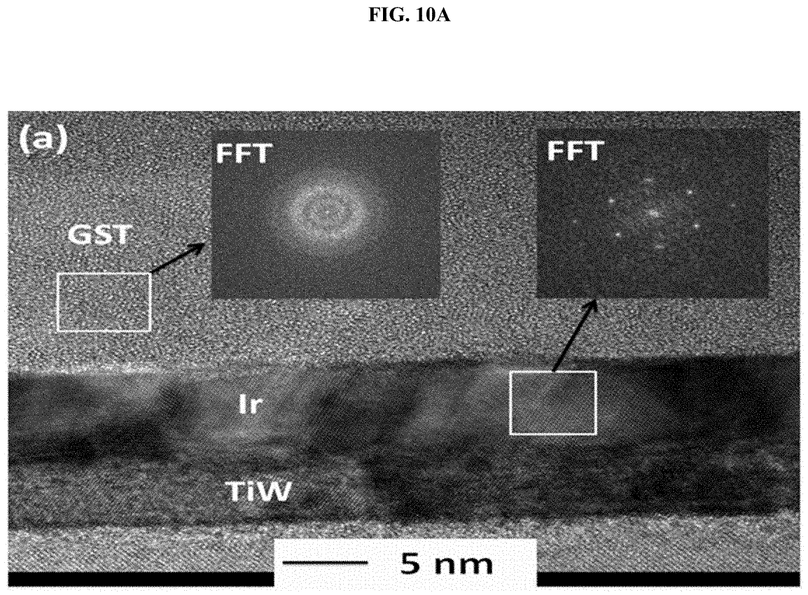

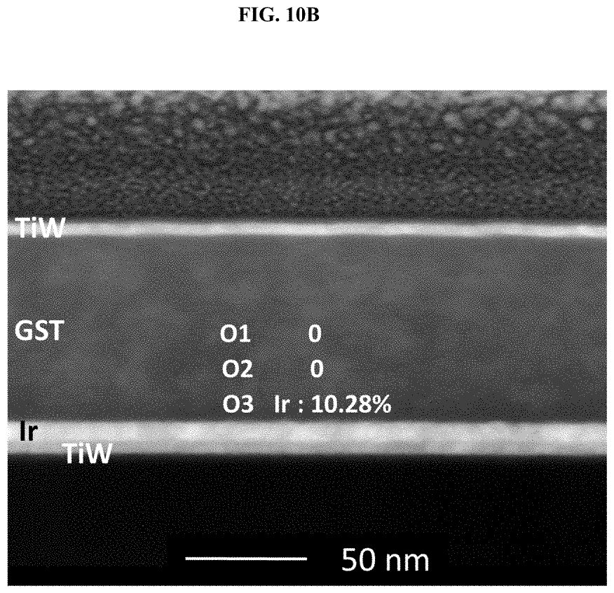

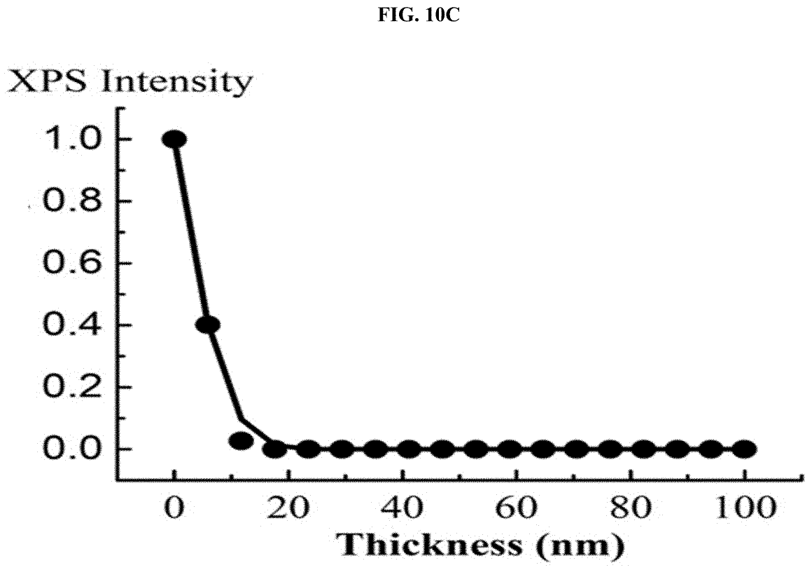

The cross-sectional TEM images of the sample with as-deposited multilayer structure are illustrated in FIGS. 10A-B. The high-resolution transmission electron microscopy (HRTEM) images are taken from cross-sections of the sample. FIG. 10A is a high-resolution transmission electron microscopy (HRTEM) image of a sample according to various embodiments with the inset showing fast Fourier transformed (FFT) patterns. An analysis of the patterns indicates that the GST is in an amorphous phase and the Ir is in a crystalline phase. At room temperature, the diffusion and migration of elements are also observed in the multilayer structure. FIG. 10B is another high-resolution transmission electron microscopy (HRTEM) image of the sample according to various embodiments. FIG. 10C is a plot of intensity as a function of thickness (in nanometers or nm) showing the X-ray photoelectron spectroscopy (XPS) depth profile of the sample according to various embodiments. FIG. 10C reveals that the diffusion length to be about 5 nm. The compositions at points 01, 02 and 03 are listed in the inset of FIG. 10B. It was observed Ag content at point 03, which is 6 nm to the interface, is about 10.28%. These results may provide good evidence to the diffusion lengths obtained by XPS analysis.

According to the Arrhenius equation D=Do exp(−Eₐ/k_{B}T), the activation energy Eₐ and the pre-exponential factor Do may be obtained from diffusion coefficients at different temperatures.

Table 1 below list the diffusion coefficients, activation energies and the pre-exponential factors of Cu, Ag and Ir diffusion in GST at different temperatures.

A tabulation of diffusion data

| Diffusing | Host | D₀ | T | L | D |
|---|---|---|---|---|---|
| species | material | (cm²/s) | (° C.) | (nm) | (cm²/s) |
| Cu | GST | 2.1 × 10⁻¹³ | 50 | 77.8 | 8.4 × 10⁻¹⁵ |
| | | | 80 | 88.2 | 1.1 × 10⁻¹⁴ |
| Ag | GST | 1.7 × 10⁻¹³ | 50 | 69.6 | 6.7 × 10⁻¹⁵ |
| | | | 80 | 80 | 8.9 × 10⁻¹⁵ |
| Ir | GST | 8.3 × 10⁻¹⁵ | 50 | 13 | 2.3 × 10⁻¹⁶ |
| | | | 80 | 15 | 3.1 × 10⁻¹⁰ |

The results showed that diffusion coefficient for elements in GST increases with the temperature and decreases with the atomic radius of metal elements. The diffusion length and diffusion coefficient of Ir in GST are much smaller than those of Cu and Ag in GST. An element with smaller atomic radius may easily diffuse into a chalcogenide material. As such, an element such as C, Mg, Al, Si, Sc, Ti, V, Cr, Mn, Fe, Co, Ni, Cu, Zn, Ge, Zr, Mo, Ag, In and Sn may be suitable as a dopant material.

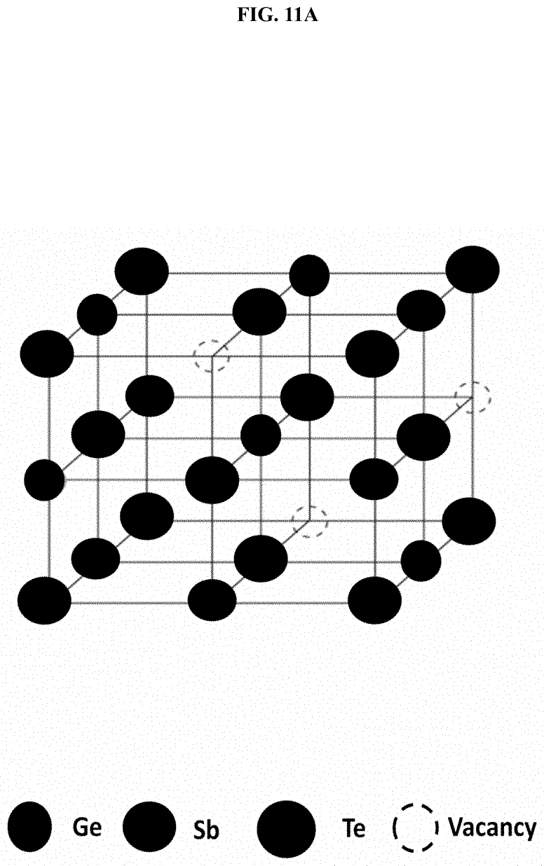

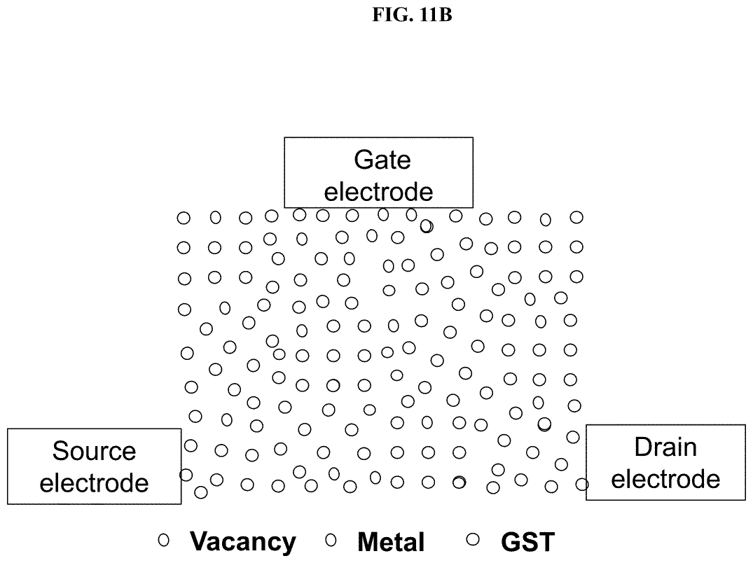

A chalcogenide material has a high number of vacancies in it. For example, germanium-antimony-tellurium Ge₂Sb₂Te₅ (GST) contains about 20% vacancy. FIG. 11A is a schematic of germanium-antimony-tellurium Ge₂Sb₂Te₅ (GST). If a vacancy position is occupied by a doped element (alternatively referred to as doped ion) in a chalcogenide material like GST, its crystal structure may be distorted, which results in the variation of band gap and depth of the trap states. Since the electrical conduction activation energy depends on the band gap and depth of the trap states, the conductance of a chalcogenide material like GST may vary with doped-element occupied vacancy position. According to an Arrhenius-type relation, the conductivity a in element-doped chalcogenide material can be expressed by

$$σ = {σ}_{0} exp ( - \frac{{E}_{σ}}{{k}_{B} T} ) \qquad ( 1 )$$

where σ₀ is a pre-exponential factor, Ea is the electrical conduction activation energy, kB is the Boltzmann constant and Tis the absolute temperature. The electrical conduction activation energy may have a simple relation with the band gap:

$${E}_{σ} = \frac{{E}_{9}}{2} + Δ E \qquad ( 2 )$$

where Eg is the band gap and ΔE is the depth of the trap states.

It is found that conductance changes with element doping in chalcogenides and depends on the doped elements and content. There are two ways to implement the element doping in chalcogenide material like GST. One method is to deposit a layer onto the chalcogenide layer including the metal element to be doped. There may be initial diffusion of the elements into the chalcogenide material during the deposition. The other method may be to form the element-doped chalcogenide by the direct sputtering of an element doped chalcogenide target.

As an element-doped chalcogenide layer is applied with a voltage, the doped-ions may shift from one vacancy to another. The ion shifts may lead to the variation of the electrical conduction activation energy in the element-doped chalcogenide layer through the change in band gap and depth of the trap states, which results in the conductance change of the electrical path.

FIG. 11B illustrates the shifting of doped ions in a germanium-antimony-tellurium (GST) layer of the device according to various embodiments. The doped-ions may shift down or up from one vacancy to another, driven by the applying electric field. The ion shift may lead to variation of electrical conduction activation energy through changing band gaps and depth of the trap states.

In summary, it is found that an element with smaller atomic radius may easily diffuse into a chalcogenide material. The diffusion length can reach 80 nm in chalcogenide material for small atoms such as Ag and Cu. Since a chalcogenide material has a relatively high concentration of vacancies, the doping element may easily occupy the vacancy sites and results in crystal structure distortion and the variation of band gap and depth of the trap states. According to these studies, a three-terminal electronic synapse device may be designed and fabricated. The stable analog characteristics and linear changes of the conductance may easily be achieved in this three-terminal synapse device. The conductance may continuously increase during the negative voltage sweeps and may decrease during the positive voltage sweeps. The device may be used to realize multiple states, and may exhibit analog switching behaviors and linear changes of the conductance.

Various embodiments may be cost-effective. Various embodiments may be CMOS compatible.

Various embodiments may relate to a three-terminal electronic synapse device including an element-doped chalcogenide layer in contact with the source electrode, the drain electrode, and the gate electrode. Various embodiments may relate to a method of forming a three-terminal electronic synapse device including forming a source electrode, a drain electrode, a gate electrode and an element-doped chalcogenide layer.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. An electronic synapse device comprising:
a body comprising a doped chalcogenide layer comprising a chalcogenide material and a dopant;
a drain electrode in contact with the body;
a source electrode in contact with the body; and
a gate electrode comprising an electrode contact layer in contact with the doped chalcogenide layer;
wherein the electrode contact layer is any one selected from a group consisting of an electrically conductive layer comprising an electrically conductive material and a dopant layer comprising the dopant.

2. The electronic synapse device according to claim 1,
wherein the electrode contact layer is the dopant layer comprising the dopant;
wherein the electrically conductive layer is on the electrode contact layer; and
wherein the doped chalcogenide layer is formed by diffusion of the dopant into an undoped chalcogenide layer.

3. The electronic synapse device according to claim 1,
wherein the electrode contact layer is a dopant layer comprising the dopant;
wherein the electrically conductive layer is on the electrode contact layer; and
wherein at least a portion of the dopant in the doped chalcogenide layer is introduced by a deposition process.

4. The electronic synapse device according to claim 1,
wherein the electrode contact layer is the electrically conductive layer comprising an electrically conductive material; and
wherein the dopant in the doped chalcogenide layer is introduced by a deposition process.

5. The electronic synapse device according to claim 1, wherein the electrically conductive material is any one selected from a group consisting of aluminum (Al), copper (Cu), silver (Ag), titanium-tungsten (TiW), and titanium nitride (TiN).

6. The electronic synapse device according to claim 1, wherein the dopant is any one selected from a group consisting of carbon (C), magnesium (Mg), aluminum (Al), silicon (Si), scandium (Sc), titanium (Ti), vanadium (V), chromium (Cr), manganese (Mn), iron (Fe), cobalt (Co), nickel (Ni), copper (Cu), zinc (Zn), germanium (Ge), zirconium (Zr), molybdenum (Mo), silver (Ag), indium (In), and tin (Sn).

7. The electronic synapse device according to claim 1, wherein the chalcogenide material is any one selected from a group consisting of GeTe, Ge₂Sb₂Te₅, GeSb₂Te₄, GeSb₄Te₇, and Sb₂Te₃.

8. The electronic synapse device according to claim 1, wherein the source electrode and the drain electrode comprise any one material selected from a group consisting of aluminum (Al), copper (Cu), silver (Ag), titanium-tungsten (TiW), and titanium nitride (TiN).

9. The electronic synapse device according to claim 1, wherein the electronic synapse device is a non-volatile memory.

10. A method of forming an electronic synapse device, the method comprising:
forming a body comprising a doped chalcogenide layer comprising a chalcogenide material and a dopant;
forming a drain electrode in contact with the body;
forming a source electrode in contact with the body; and
forming a gate electrode comprising an electrode contact layer in contact with the doped chalcogenide layer;
wherein the electrode contact layer is any one selected from a group consisting of an electrically conductive layer comprising an electrically conductive material and a dopant layer comprising the dopant.

11. The method according to claim 10,
wherein the electrode contact layer is the dopant layer comprising the dopant;
wherein the electrically conductive layer is on the electrode contact layer;
wherein the doped chalcogenide layer is formed by diffusion of the dopant into an undoped chalcogenide layer.

12. The method according to claim 10,
wherein the electrode contact layer is a dopant layer comprising the dopant;
wherein the electrically conductive layer is on the electrode contact layer; and
wherein at least a portion of the dopant in the doped chalcogenide layer is introduced by a deposition process.

13. The method according to claim 10,
wherein the electrode contact layer is the electrically conductive layer comprising an electrically conductive material; and
wherein the dopant in the doped chalcogenide layer is introduced by a deposition process.

14. The method according to claim 10, wherein the electrically conductive material is any one selected from a group consisting of aluminum (Al), copper (Cu), silver (Ag), titanium-tungsten (TiW), and titanium nitride (TiN).

15. The method according to claim 10, wherein the drain electrode, the source electrode, the gate electrode and the body are formed by any one deposition process selected from a group consisting of atomic layer deposition (ALD), chemical vapor deposition (CVD), pulsed laser deposition (PLD), molecular-beam epitaxy (MBE) and physical vapor deposition (PVD).

16. The method according to claim 10, wherein the body comprising the doped chalcogenide layer is formed before forming the source electrode and the drain electrode.

17. The method according to claim 10, further comprising:
forming one or more further chalcogenide layers and forming one or more further dopant layers.

18. The method according to claim 10, wherein the chalcogenide layer and the one or more chalcogenide layers form an alternating arrangement with the dopant layer and the one or more further dopant layers.

19. The method according to claim 10, wherein the dopant is any one selected from a group consisting of carbon (C), magnesium (Mg), aluminum (Al), silicon (Si), scandium (Sc), titanium (Ti), vanadium (V), chromium (Cr), manganese (Mn), iron (Fe), cobalt (Co), nickel (Ni), copper (Cu), zinc (Zn), germanium (Ge), zirconium (Zr), molybdenum (Mo), silver (Ag), indium (In), and tin (Sn).

20. The method according to claim 10, wherein the chalcogenide material is any one selected from a group consisting of GeTe, Ge₂Sb₂Te₅, GeSb₂Te₄, GeSb₄Te₇, and Sb₂Te₃.
